(19) United States
(12) Patent Application Publication
(10) Pub. No.: US 2022/0356555 A1
(43) Pub. Date: Nov. 10, 2022

(54) SUPERALLOY AIRCRAFT PART COMPRISING A COOLING CHANNEL

(71) Applicant: SAFRAN, Paris (FR)

(72) Inventors: Amar SABOUNDJI, MOISSY-CRAMAYEL (FR); Jérémy RAME, MOISSY-CRAMAYEL (FR)

(73) Assignee: SAFRAN, Paris (FR)

(21) Appl. No.: 17/774,187

(22) PCT Filed: Nov. 5, 2020
(86) PCT No.: PCT/FR2020/052002

§ 371 Date: May 4, 2022

(30) Foreign Application Priority Data
Nov. 5, 2019 (FR) 1912379

(51) Int. Cl. C23C 10/10; C23C 10/60; C22C 19/05

(52) U.S. Cl. CPC C23C 10/10; C23C 10/60; C22C 19/057

(57) ABSTRACT

A part includes a substrate made of a nickel-based superalloy, the substrate having a first average mass fraction of one or more first elements chosen from hafnium, silicon and chromium, the substrate having an open cavity in the part and a cooling channel, the substrate further including a surface layer partially forming the cavity, the surface layer having a second average mass fraction of the first element or first elements which is greater than the first average mass fraction.

### FIELD OF THE INVENTION

The invention relates to an aircraft part, such as a turbine blade or distributor blade.

### STATE OF THE ART

In a turbojet, the exhaust gases generated by the combustion chamber can reach high temperatures, for example greater than 1200° C., if not 1600° C. The turbojet parts, in contact with these exhaust gases, such as turbine blades for example, must thus be able to retain their mechanical properties at these high temperatures.

To this end, it is known practice to manufacture certain “superalloy” turbine parts. Superalloys are a family of high-resistance metal alloys that can function at temperatures relatively close to their melting points (typically 0.7 to 0.8 times their melting temperature).

Nevertheless, a superalloy part always has a limit operating temperature above which creep of the part is too great for the part to be used.

To this end, it is known practice to manufacture aircraft parts comprising one or more cooling channels. A fluid, such as a gas leaving a low-pressure compressor, can be introduced into the cooling channel(s). Its circulation thus allows the part to be cooled.

Nevertheless, the walls of the cooling channel(s) are sensitive to the environment. In particular these walls can be oxidised and/or corroded during use of the part, which decreases its usage time.

### SUMMARY OF THE INVENTION

One aim of the invention is to is to propose a solution for manufacturing a turbine part comprising a cooling channel less sensitive to oxidation and/or corrosion than the cooling channels of the prior art.

This aim is achieved within the scope of the present invention as a result of a part comprising a substrate made of a nickel—based superalloy, the substrate having a first average mass fraction of one or more first elements chosen from hafnium, silicon and chromium, the substrate comprising at least one open cavity in the part and preferably a cooling channel, the substrate further comprising a surface layer at least partially forming the cavity, the surface layer having a second average mass fraction of the first element(s) which is strictly greater than the first average mass fraction.

The invention is advantageously completed by the following characteristics, taken individually or in any one of their technically possible combinations:
the part further comprises a coating covering the surface layer, the coating having a mass fraction of the first element(s) greater than 50%, and preferably greater than 90%,
the thickness /₂ of the protective coating being at least greater than 50 nm,
the first element is hafnium and the second mass fraction is between 0.4% and 4.5%,
the first element is silicon, and the second mass fraction is between 4% and 10%,
the first element is chromium and the second mass fraction is between 0.2% and 5%,
the substrate includes rhenium and/or ruthenium, the rhenium and/or ruthenium average mass fraction of the substrate being greater than or equal to 3%, and preferably greater than or equal to 4%,
the part is a turbine part.

Another aspect of the invention is an aircraft turbine comprising a part according to the invention.

Another aspect of the invention is an aircraft comprising a part according to the invention.

Another aspect of the invention is a method for manufacturing an aircraft part according to the invention, comprising at least the following steps:
provision of a part comprising a substrate made of a nickel-based superalloy, the substrate comprising at least one open cavity in the part,
depositing on at least one part of the cavity of at least one layer of one or more first elements chosen from hafnium, silicon and chromium,
heat treatment of the substrate and the layer such that the first element(s) of the layer diffuse(s) into the substrate.

The invention is advantageously completed by the following characteristics, taken individually or in any one of their technically possible combinations:
heat treatment is carried out in a vacuum chamber or in a chamber comprising inert gas(es), preferably at least one gas chosen from argon and helium,
the heat treatment step is carried out for a period of one to eight hours, in a chamber in which the temperature is set between 700° C. and 1300° C. and preferably between 900° C. and 1250° C.

Another aspect of the invention is a method for cooling an aircraft part, wherein the part complies with the invention, the method comprising a step of injecting a cooling fluid in the cavity.

### DESCRIPTION OF THE DRAWINGS

Other characteristics, aims and advantages of the invention will emerge from the description which follows, which is purely illustrative and not limiting, and which should be read with reference to the appended drawings in which:

FIG. 1 schematically illustrates a section of an aircraft part, for example a turbine blade, or distributor blade, comprising a cooling channel,

FIG. 2 schematically illustrates a method for manufacturing a part according to one embodiment of the invention,

FIG. 3 schematically illustrates the wall of a cooling channel during the manufacture of a part according to one embodiment of the invention,

FIG. 4 schematically illustrates the wall of a cooling channel during the manufacture of a part according to one embodiment of the invention,

FIG. 5 schematically illustrates the wall of a cooling channel of a part according to one embodiment of the invention,

FIG. 6 is a microphotograph of the wall of a cooling channel during the manufacture of a part according to one embodiment of the invention,

FIG. 7 is a microphotograph of the wall of a cooling channel of a part according to one embodiment of the invention.

In the set of figures, similar elements have identical references.

### DEFINITIONS

The term “superalloy” refers to an alloy having, at high temperatures and high pressure, very good resistance to oxidation, corrosion, creep and cyclic constraints (especially mechanical or thermal). Superalloys have a particular application in the manufacture of parts used in aeronautics, for example turbine blade, as they constitute a family of high-resistance metal alloys which can work at temperatures relatively close to their melting points (typically 0.7 to 0.8 times their melting temperature).

A superalloy can have a biphasic microstructure comprising a first phase (called “γ phase”) forming a matrix, and a second phase (called “γ′ phase”) forming precipitates which harden in the matrix. The coexistence of these two phase is designated by the phrase “γ-γ′ phase”.

The “base” of the superalloy refers to the main metal component of the matrix. In most cases, superalloys comprise an iron, cobalt or nickel base, but also sometimes a titanium or aluminium base. The superalloy base if preferably a nickel base.

The “nickel-based superalloys” have the advantage of offering a good compromise between resistance to oxidation, resistance to rupture at high temperature and weight, which justifies their use in the hottest part of the turbojet.

Nickel-based superalloys consist of a γ phase (or matrix) of the γ—Ni face-centred cubic austenitic type, possibly containing additives in solid solution with a substitution (Co, Cr, W, Mo) and a γ′ phase (or precipitates) of the type γ′—Ni₃X, with X=Al, Ti or Ta. The γ′ phase has an ordered L12 structure, derived from the face-centred cubic structure, coherent with the matrix, that is to say, having an atomic mesh very similar to it.

By virtue of its well-ordered nature, the γ′ phase has the remarkable property of having mechanical resistance which increases with the temperature up to about 800° C. The very strong coherence between the γ and γ′ phases confers a very high hot mechanical resistance to nickel—based superalloys, which is itself dependant on the γ/γ′ ratio and the size of the hardening precipitates.

A superalloy is preferably rich in rhenium and/or ruthenium, that is to say, the average mass fraction in rhenium and ruthenium of the superalloy is greater than or equal to 3%, and preferably to 4%, allowing increased creep resistance of the superalloy parts compared to superalloys without rhenium.

A superalloy is preferably generally poor in chromium, that is to say, the average mass fraction in chromium throughout the superalloy is less than 5%, preferably less than 3%. In fact, chromium depletion during rhenium and/or ruthenium enrichment of the superalloy makes it possible to retain a stable allotropic structure, especially a γ/γ′ phase,

The term “mass fraction” refers to the ratio of the mass of an element or group of elements to the total mass.

By “protective coating” is meant a layer covering the substrate and allowing it to be chemically and/or mechanically protected. The protective coating preferably prevents corrosion and/or oxidation of the substrate. Preferably, the protective coating may be a bonding layer between the substrate and a heat protection layer.

By “open cavity” of a part is meant a cavity linked to the exterior of the part.

By “secondary vacuum” is meant a vacuum in which the atmosphere is set at a pressure between 10⁻⁷ millibars and 10⁻³ millibars excluded.

By “primary vacuum” is meant a vacuum in which the atmosphere is set at a pressure between 10^{—3} millibars and 1 millibar.

### DETAILED DESCRIPTION OF THE INVENTION

Substrate 2

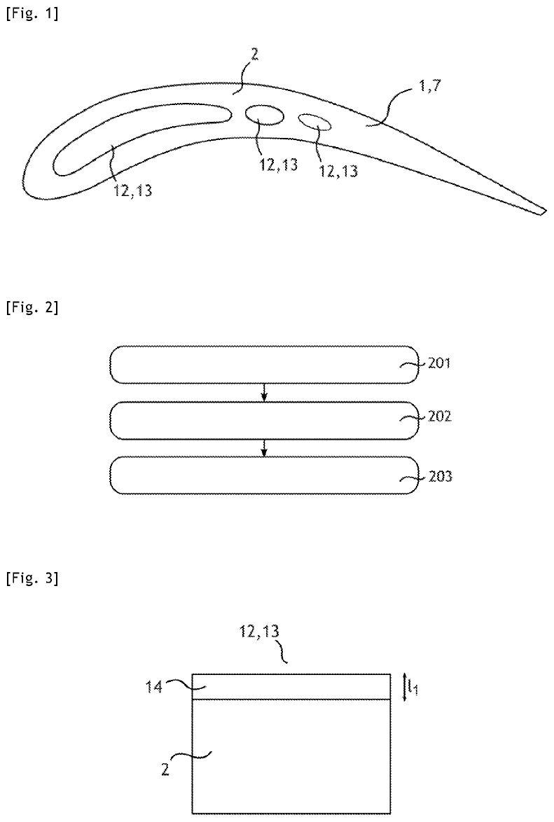

With reference to FIG. 1, a part 1 of an aircraft comprises a substrate 2 made of monocrystalline superalloy. The aircraft part is preferably a turbine part. The monocrystalline superalloy is preferably a nickel—based superalloy but can also be a cobalt—based superalloy, for example obtained by an equiaxed casting method or by directed solidification. The substrate 2 preferably has a predominantly γ—γ′ phase. The substrate 2 can also include rhenium and/or ruthenium, the average mass fraction of rhenium and/or ruthenium being greater than or equal to 3%, and preferably greater than or equal to 4%, allowing creep resistance of the superalloy part to be increased compared to superalloy parts without rhenium and/or ruthenium.

The substrate 2 preferably has a low first average mass fraction in chromium throughout the substrate, that is to say, less than 5%. Thus, the substrate presents mechanical properties of creep resistance at a high temperature superior to a substrate with a first average mass fraction in chromium greater than 5%. Table 1 gives examples of the composition of the substrate 2, as an average mass fraction of each element throughout the substrate 2.

TABLE 1

| | Substrate elements in a superalloy (average mass fraction in %) | | | | | | | | | | |
|---|---|---|---|---|---|---|---|---|---|---|---|
| | Ni | Al | Co | Cr | Mo | Re | Ta | Ti | W | Cb | Ru |
| A | Base | 5.2 | 6.5 | 7.8 | 2 | 0 | 7.9 | 1.1 | 5.7 | | |
| B | Base | 5.6 | 9 | 6.5 | 0.6 | 3 | 6.5 | 1 | 6 | | |
| C | Base | 5.73 | 9.6 | 3.46 | 0.6 | 4.87 | 8.28 | 0.86 | 5.5 | | |
| D | Base | 5.7 | 3 | 2 | 0.4 | 6 | 8 | 0.2 | 5 | 0.1 | |
| E | Base | 5.8 | 12.5 | 4.2 | 1.4 | 5.4 | 7.2 | 0 | 6 | | |
| F | Base | 6 | <0.2 | 4 | 1 | 4 | 5 | 0.5 | 5 | | 4 |

With reference to FIG. 1, the substrate 2 forms at least one cavity 12 in the part 1. Preferably the cavity 12 is a cooling channel 13 of the part 1. The cooling channel 13 can have a cooling fluid inlet and a cooling fluid outlet. It is thus possible to introduce a cooling fluid such as a gas emitted from a low-pressure compressor, in a cooling channel of the part, so as to reduce the temperature of the part during its use.

Method for manufacturing the part 1 and protecting the cavity 12

With reference to FIG. 2, one aspect of the invention is a method for manufacturing an aircraft part. Such a method comprises a step 201 of providing a part including a substrate 2 such as that described previously. Such a substrate 2 has already been subjected to the steps of solution-forming the eutectics and quenching.

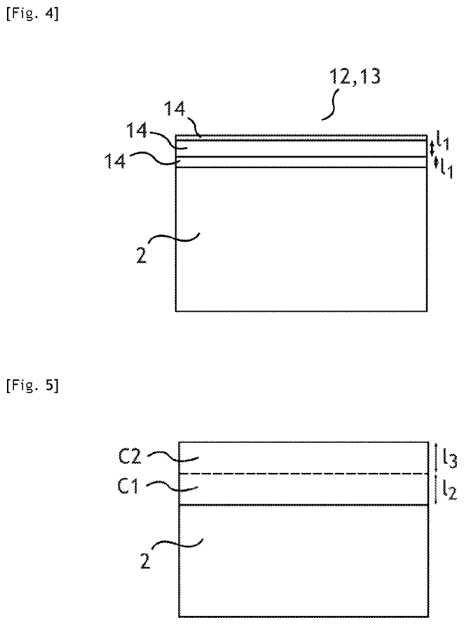

With reference to FIG. 3 and FIG. 4, the method includes a step 202 of depositing, on at least one part of the cavity 12, of at least one treatment layer 14 of a first element chosen from hafnium, silicon and chromium. With reference to FIG. 3, several layers 14, each layer 14 comprising a different element chosen from hafnium, silicon and chromium, may be deposited on at least one part of the cavity 12.

The thickness /₁of the layer 14 deposited during step 102 can be between 10 nm and 10 μm. When the first element is hafnium, the thickness /₁ of the layer 14 deposited is preferably between 50 nm and 500 nm. When the first element is silicon, the thickness /₁ of the layer 14 deposited is preferably between 100 nm and 500 nm. When the first element is chromium, the thickness /₁ of the layer 14 deposited is preferably between 0.5 micrometres and 3 micrometres.

Depositing of the layer(s) 14 on the cavity 12 can be carried out by vapour phase chemical deposits (CVD), such as PECVD, LPCVD, UHVCVD, APCVD, ALCVD, UHVCVD.

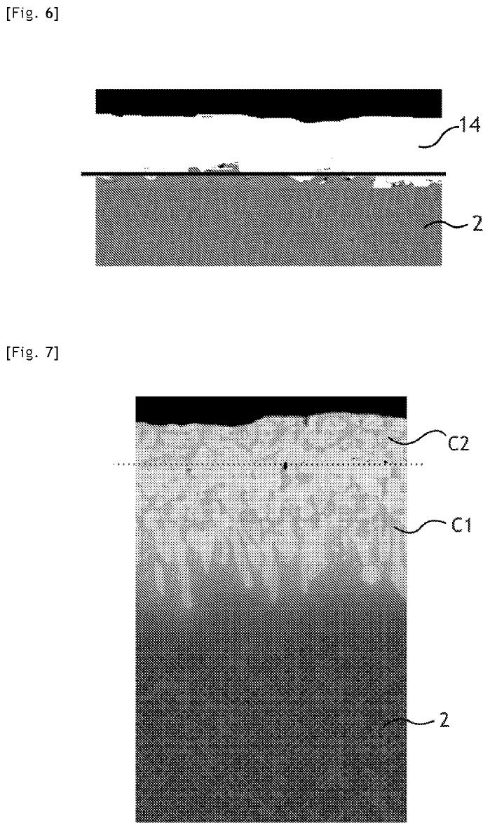

With reference to FIG. 2, FIG. 5, FIG. 6 and FIG. 7, the method comprises a step 203 of heat treating the substrate 2 and the layer 14 so as to diffuse the first element(s) of the layer 14 into the substrate 2. Thus, the first element(s) of the layer 14 diffuse(s) in the substrate 2, in such a manner as to form a surface layer C1 in the substrate 2. A second average mass fraction of the first element(s) in the surface layer Cl is strictly greater than the first average mass fraction of the first element in the substrate 2. Thus, it is possible to protect the cavity 12, and preferably the cooling channel(s) 13, from oxidation and/or corrosion, while maintaining a sufficiently low average mass fraction in chromium, hafnium and/or silicon in the substrate 2.

With reference to FIG. 7, after step 203, the substrate 2 includes the surface layer C1, and is covered with a coating C2, resulting from layer 14 deposited prior to heat treatment step 203. The coating C2 may include only the first element(s).

Nonetheless, it is possible that, during the heat treatment step 203, certain elements of the substrate 2 are incorporated into the layer 14. Thus, the coating C2 has a mass fraction of the first element(s) greater than 50%, and preferably greater than 90%. The thickness /₂ of the surface layer C1 is greater than 50 nm, that is, at the length characteristic of diffusion of the first element(s). The thickness /₂ can in particular be greater than 100 nm, and preferably between 100 nm and 100 μm. The coating C2 has a thickness /₃ between 50 nm and 100 μm.

Preferably, the surface layer C1 has a second mass fraction of the first element adapted to form a protective coating by oxidation of the first element. When the first element is hafnium, the second mass fraction can preferably be between 0.4% and 4.5%. When the first element is silicon, the second mass fraction can be preferably between 4% and 10%. When the first element is chromium, the second mass fraction can preferably be between 0.2% and 5%.

The substrate 2 and the layer(s) 14 obtained during step 202 may be, for example, placed in a chamber to carry out the heat treatment step 203. During the heat treatment step 203, the chamber can be put under vacuum, or filled with one or more inert gases, such as argon and/or helium. Preferably, a secondary vacuum can be maintained inside the chamber. Preferably, a primary vacuum can be set inside the chamber, the primary vacuum being made up of at least one element chosen from argon, helium and dihydrogen. Thus, it is possible to avoid oxidation of the surface of the substrate 2 during the heat treatment step 203. Preferably, the heat treatment step 203 comprises a temperature rise sub-step in which the temperature in the chamber is set so as to increase at a rate of 5 to 100° C. per minute. Preferably, the heat treatment step is carried out for one to eight hours, in a chamber in which the temperature is set between 700° C. and 1300° C., and preferably between 900° C. and 1250° C. Above 700° C., and preferably above 900° C., the first element(s) diffuse(s) into the substrate 2. The temperature is set below 1300° C., and preferably below 1250° C., so as not to degrade the superalloy.

1-14. (canceled)

15. A part comprising a substrate made of a nickel—based superalloy, which has a first average mass fraction of one or more first elements chosen from hafnium, silicon and chromium and which comprises at least one open cavity in the part,
wherein the substrate comprises a surface layer at least partially forming the open cavity, the surface layer having a second average mass fraction of the one or more first elements which is greater than the first average mass fraction and wherein when the first element is hafnium then the second mass fraction is between 0.4% and 4.5%, when the first element is silicon then the second mass fraction is between 4% and 10% and when the first element is chromium then the second mass fraction is between 0.2% and 5%.

16. The part according to claim 15, further comprising a coating, covering the surface layer, the coating having a mass fraction of the one or more first elements greater than 50%.

17. The part according to claim 15, wherein a thickness of the surface layer is at least greater than 50 nm.

18. The part according to claim 15, wherein the substrate includes rhenium and/or ruthenium, the rhenium and/or ruthenium average mass fraction of the substrate being greater than or equal to 3%.

19. The part according to claim 15, wherein the part is an aircraft part.

20. An aircraft turbine comprising the part according to claim 19.

21. An aircraft comprising the part according to claim 19.

22. A method for manufacturing the aircraft part according to the part of claim 19, the method comprising:
providing a part comprising substrate made of a nickel-based superalloy, the substrate comprising at least one open cavity in the part,
depositing on at least one part of the open cavity of at least one layer of one or more first elements chosen from hafnium, silicon and chromium,
heat treating the substrate and the layer such that the one or more first element of the layer diffuses into the substrate.

23. The method according to claim 22, wherein the heat treatment is carried out in a vacuum chamber or in a chamber comprising one or more inert gasses.

24. The method according to claim 22, wherein the heat treatment step is carried out for a period of one to eight hours, in a chamber in which the temperature is set between 700° C. and 1300° C.

25. A method for cooling the aircraft part according to claim 19, the method comprising a step of injecting a cooling fluid in the open cavity.

26. The part according to claim 15, wherein the open cavity is a cooling channel.

27. The part according to claim 15, further comprising a coating, covering the surface layer, the coating having a mass fraction of the one or more first elements greater than 90%.

28. The part according to claim 15, wherein the substrate includes rhenium and/or ruthenium, the rhenium and/or ruthenium average mass fraction of the substrate being greater than or equal to 4%.

29. The method according to claim 23, wherein the one or more inert gasses are chosen from argon and helium.

30. The method according to claim 22, wherein the heat treatment step is carried out for a period of one to eight hours, in a chamber in which the temperature is set between 900° C. and 1250° C.
